(19) United States
(12) Patent Application Publication
(10) Pub. No.: US 2025/0034362 A1
(43) Pub. Date: Jan. 30, 2025

(54) CUREABLE RESIN COMPOSITION, THIN LAYER MANUFACTURED THEREFROM, COLOR CONVERSION PANEL, AND DISPLAY DEVICE INCLUDING THIN LAYER

(71) Applicant: SAMSUNG SDI CO., LTD., Yongin-si (KR)

(72) Inventors: Sangran KOH, Suwon-si (KR); Sungkeun LEE, Suwon-si (KR); Jong Hyun RHO, Suwon-si (KR); Jeehyun RYU, Suwon-si (KR); Hyun-Joo SEO, Suwon-si (KR); Dongju SHIN, Suwon-si (KR); Donggyoon SEO, Suwon-si (KR)

(21) Appl. No.: 18/782,208

(22) Filed: Jul. 24, 2024

(30) Foreign Application Priority Data
Jul. 24, 2023 (KR) 10-2023-0096301

(51) Int. Cl. C08K 7/26; C08G 77/20; C08K 9/06

(52) U.S. Cl. CPC C08K 7/26; C08G 77/20; C08K 9/06; C08K 2201/003; C08K 2201/011

(57) ABSTRACT

A curable resin composition, a thin layer manufactured from the curable resin composition, a color conversion panel including the thin layer, and a display device including the thin layer, the curable resin composition including a silicon-containing polymer represented by Chemical Formula 1, hollow particles, and a solvent:

(R⁴R⁵R⁶SiO_{1/2})_{M}(R⁷R⁸SiO_{2/2})_{D}(R⁹SiO_{3/2})_{T1}(SiO_{3/2}—Y—SiO_{3/2})_{T2}(SiO_{4/2})_{Q} [Chemical Formula 1].

### CROSS-REFERENCE TO RELATED APPLICATION

This application claims priority to and the benefit of Korean Patent Application No. 10-2023-0096301 filed in the Korean Intellectual Property Office on Jul. 24, 2023, the entire contents of which are incorporated herein by reference.

### BACKGROUND

### 1. Field

Embodiments relate to a curable resin composition, a thin layer manufactured therefrom, and a color conversion panel and a display device including the thin layer.

### 2. Description of the Related Art

As the display field develops, various display devices using displays are becoming more diverse, and among these display devices, there may be a continuous demand for technology to increase the luminous efficiency of self-luminous materials such as OLED or display devices including quantum dots. If low-refractive materials are used between the various thin layers of the panel that forms the display, luminous efficiency may be increased by recycling the light lost when light moves inside. Additionally, because the low refractive characteristics may produce a low reflectance effect, it may be used as a low-reflection layer of a lens outside a light sensor, or as an anti-reflection (AR) film on the outermost layer of a display or solar cell.

Recently, display devices may need to be thinner, lighter, bendable and rollable, and the introduction of thin and flexible films may be considered to realize these characteristics. The lower the refractive index of the low-refraction coating layer, the lower the thickness of the coating layer, which may increase a margin of the coating layer and the efficiency according to the device purpose. Meanwhile, in addition to the task of lowering the refractive index of low-refractive materials, there may be a need to improve thermal stability, excellent adhesion to the upper and lower films, high transparency, and crack resistance to prevent cracks from occurring at high thickness if manufacturing or using display devices.

### SUMMARY

Embodiments are directed to a curable resin composition, including a silicon-containing polymer represented by Chemical Formula 1; hollow particles; and a solvent:

(R⁴R⁵R⁶SiO_{1/2})_{M}(R⁷R⁸SiO_{2/2})_{D}(R⁹SiO_{3/2})_{T1}(SiO_{3/2}—Y—SiO_{3/2})_{T2}(SiO_{4/2})_{Q} [Chemical Formula 1]

wherein, in Chemical Formula 1, R⁴ to R⁹ are each independently hydrogen, or a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C6 to C30 aryl group, a substituted or unsubstituted C3 to C30 cycloalkyl group, a substituted or unsubstituted C2 to C30 heterocycloalkyl group, a substituted or unsubstituted C1 to C30 alkoxy group, a carboxyl group, R(C═O)—, R(C═O)O—, wherein, R is hydrogen, a C1 to C30 alkyl group, a C3 to C30 cycloalkyl group, a C6 to C30 aryl group, or a combination thereof, an epoxy group-containing monovalent organic group, a (meth)acryloyloxy group, a (meth)acrylate group, an aminoalkyl group, or a combination thereof, Y is a substituted or unsubstituted C1 to C30 alkylene group, a substituted or unsubstituted C2 to C30 alkenylene group, a substituted or unsubstituted C3 to C30 cycloalkylene group, a substituted or unsubstituted C6 to C30 arylene group, or a combination thereof, 0≤M≤0.2, 0<D<0.2, 0.1<T1≤0.5, 0≤T2≤0.2, 0<Q≤0.65, and M+D+T1+T2+Q=1.

In Chemical Formula 1, 0≤M≤0.1, 0<D≤0.15, 0.2≤T1≤0.5, and 0.3≤Q≤0.65.

In Chemical Formula 1, 0≤M≤0.1, 0.01≤D≤0.1, 0.3≤T1≤0.45, and 0.5≤Q≤0.6.

The silicon-containing polymer may have a polystyrene converted weight average molecular weight of about 1,000 g/mol to about 100,000 g/mol.

The silicon-containing polymer may be included in an amount of about 1 wt % to about 50 wt %, based on a total weight of the curable resin composition.

The curable resin composition may have a pH of about 4 to about 10.

The hollow particles may have an average diameter (D₅₀) of about 10 nm to about 300 nm.

The hollow particles may have an average porosity of about 40% to about 90%.

The hollow particles may be hollow silica and the hollow silica may include a silane compound on its surface.

The hollow particles may be included in an amount of about 1 wt % to about 35 wt %, based on a total weight of the curable resin composition.

The curable resin composition may further include a fluorine surfactant or a siloxane surfactant.

The embodiments may be realized by providing a thin layer manufactured from the curable resin composition.

The embodiments may be realized by providing a color conversion panel including the thin layer.

The embodiments may be realized by providing a display device including the color conversion panel.

### BRIEF DESCRIPTION OF THE DRAWINGS

Features will become apparent to those of skill in the art by describing in detail exemplary embodiments with reference to the attached drawings in which:

FIG. 1 is a plan view schematically showing a color conversion panel according to some embodiments.

FIG. 2 is a cross-sectional view schematically showing a cross-section taken along line II-II in FIG. 1.

FIG. 3 is a cross-sectional view according to a modification of FIG. 2.

FIG. 4 is a cross-sectional view according to a modified example of FIGS. 2 and 3.

FIG. 5 is a cross-sectional view according to a modification of FIG. 2.

FIG. 6 is a transmission electron microscope (TEM) photograph showing that cracks do not occur in the cured layer according to Example 3 even when the thickness is about 4 μm or more.

FIG. 7 is a scanning electron microscope (SEM) photograph showing cracks occurring in a panel to which the cured layer according to Comparative Example 1 was applied.

FIG. 8 is an SEM photograph showing cracks occurring in a panel to which the cured layer according to Comparative Example 2 was applied.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Some embodiments relate to a curable resin composition that may also have excellent optical characteristics such as low refractive index and low haze, and excellent mechanical properties such as high indentation hardness and crack resistance.

As the display field develops, various display devices using displays are becoming more diverse, and among these display devices, there may be a continuous demand for technology to increase the luminous efficiency of self-luminous materials such as OLED or display devices including quantum dots. Using low refractive index characteristics, efficiency may be increased by reducing light loss inside the device through which light moves. In addition, low refractive index materials may have low reflectance characteristics, so that they can be used as a low-reflection layer of a lens outside a light sensor, or as an anti-reflection (AR) film on the outermost layer of a display or solar cell. Meanwhile, the lower the refractive index of the low-refraction coating layer, the lower the thickness of the coating layer may be, which may increase the margin of the coating layer and efficiency of the device in accordance with its purpose.

Among other methods for obtaining low refractive index materials, if using a thermosetting resin, the resin may be cured at a high temperature of about 350° C. or higher, or at least about 300° C. or higher, to form nanopores. Methods such as chemical vapor deposition (CVD) may not only require expensive equipment, but it may also be difficult to form a thick coating layer, and it may also be difficult to generate nanopores, making it difficult to manufacture thin layers having a low refractive index. If using fluorine compounds or epoxy polymers, it may be difficult to achieve a low refractive index, and even if it may be achieved, cracks may be highly likely to occur if the thickness rises to the micrometer level.

It may be easy to implement a low refractive index in the case of silicon materials, but as the thickness increases, the transparency of the coating layer may decrease and become cloudy, and cracks may begin to appear on the entire surface above a certain thickness, e.g., about 2.5 μm or more. In addition, even if the crack resistance of the low refractive index film may be improved, panel cracks may occur if the indentation hardness does not have mechanical properties of at least about 0.12 GPa or more. In particular, if there is a layer with the same pattern as the color filter layer under the layer implementing a low refractive index, the substrate may not be flat and have steps due to the pattern. If a coating of a low refractive index layer fills the gaps between the steps of the lower pattern, the thickness of the low refractive index layer filled in the gaps may become very thick. In this case, there may be a possibility that cracks may occur in the thickened low refractive index layer in that area. Therefore, using some methods it may be difficult to implement a thick film that has low refractive index and low haze characteristics, but also does not generate cracks and has excellent mechanical properties.

The curable resin composition according to some embodiments may be curable at low temperatures, e.g., less than or equal to about 300° C., less than or equal to about 280° C., less than or equal to about 270° C., less than or equal to about 250° C., or less than or equal to about 240° C., and the layer manufactured therefrom may have a low refractive index, e.g., less than or equal to about 1.35, and a low haze, e.g., less than or equal to about 5%, showing excellent optical characteristics while exhibiting excellent indentation hardness, e.g., indentation hardness of greater than or equal to about 0.12 GPa, and improved mechanical properties such as high crack resistance, e.g., crack resistance at a thickness of greater than or equal to about 5 μm. Therefore, the curable resin composition according to some embodiments may be advantageously used as a material for forming a low refractive index layer of various display devices, e.g., a display device including a quantum dot color filter having a step difference due to a pattern.

This curable resin composition may include a silicon-containing polymer that satisfies a specific chemical formula, hollow particles, and a solvent as main ingredients, and may further include additives such as surfactants to improve coating properties and prevent unevenness.

Hereinafter, each component of the curable resin composition according to some embodiments will be described in detail.

### (a) Silicon-Containing Polymer

The silicon-containing polymers may be known as low refractive index materials, and a curable resin composition according to some embodiments may include a siloxane copolymer represented by Chemical Formula 1:

(R⁴R⁵R⁶SiO_{1/2})_{M}(R⁷R⁸SiO_{2/2})_{D}(R⁹SiO_{3/2})_{T1}(SiO_{3/2}—Y—SiO_{3/2})_{T2}(SiO_{4/2})_{Q} [Chemical Formula 1]

In Chemical Formula 1, R⁴ to R⁹ may each independently be or include, e.g., hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C6 to C30 aryl group, a substituted or unsubstituted C3 to C30 cycloalkyl group, a substituted or unsubstituted C2 to C30 heterocycloalkyl group, a substituted or unsubstituted C1 to C30 alkoxy group, a carboxyl group, R(C═O)—, R(C═O)O— (wherein, R may be or include, e.g., hydrogen, a C1 to C30 alkyl group, a C3 to C30 cycloalkyl group, a C6 to C30 aryl group, or a combination thereof), an epoxy group-containing monovalent organic group, a (meth)acryloyloxy group, a (meth)acrylate group, an aminoalkyl group, or a combination thereof.

Y may be or include, e.g., a substituted or unsubstituted C1 to C30 alkylene group, a substituted or unsubstituted C2 to C30 alkenylene group, a substituted or unsubstituted C3 to C30 cycloalkylene group, a substituted or unsubstituted C6 to C30 arylene group, or a combination thereof.

$$0 \leq M \leq 02 , 0 < D < 0.2 , 0.1 < T 1 \leq 0.5 , 0 \leq T 2 \leq 0.2 , 0 < Q \leq 0.6 5.$$

$$M + D + T 1 + T 2 + Q = 1 .$$

In Chemical Formula 1, 0≤M≤0.1, 0<D≤0.15, 0.2≤T1≤0.5, 0≤T2≤0.2, 0.3≤Q≤0.65, and M+D+T1+T2+Q=1, e.g., 0≤M≤0.1, 0.01≤D≤0.1, 0.3≤T1≤0.45, 0≤T2≤0.2, 0.5≤Q≤0.6, and M+D+T1+T2+Q=1, or 0≤M≤0.1, 0.01≤D≤0.05, 0.35≤T1≤0.45, 0≤T2≤0.2, 0.55≤Q≤0.6, and M+D+T1+T2+Q=1.

If the curable resin composition according to some embodiments includes the siloxane copolymer as a polymer matrix, the layer manufactured from the composition may have a low refractive index and low haze, thereby maintaining high transparency, while at the same time having high indentation hardness and excellent crack resistance that suppresses the occurrence of cracks even when the thickness increases.

In Chemical Formula 1, R⁴ to R⁹ may each independently be, e.g., a substituted or unsubstituted C1 to C10 alkyl group, a substituted or unsubstituted C3 to C10 cycloalkyl group, a substituted or unsubstituted C2 to C10 heterocycloalkyl group, an epoxy group-containing monovalent organic group, a substituted or unsubstituted C6 to C20 aryl group, a (meth)acryloyl group, a (meth)acrylate group, an aminoalkyl group, a C1 to C10 alkyl group substituted with a (meth)acryloyl group, a C1 to C10 alkyl group substituted with a (meth)acrylate group, or a combination thereof.

In Chemical Formula 1, R⁴ to R⁹ may each independently be, e.g., a C1 to C4 alkyl group, a C2 to C10 heterocycloalkyl group, a glycidoxypropyl group, a C6 to C10 aryl group, a (meth)acryloyl group, a (meth)acrylate group, a C1 to C4 alkyl group substituted with a (meth)acryloyl group, a C1 to C4 alkyl group substituted with a (meth)acrylate group, a C1 to C4 alkyl group substituted with an amino group, or a combination thereof.

In Chemical Formula 1, Y may be, e.g., a C1 to C10 alkylene group, a C4 to C10 cycloalkylene group, a C6 to C20 arylene group, or a combination thereof.

A polystyrene converted weight average molecular weight of the siloxane copolymer represented by Chemical Formula 1 may be, e.g., about 1,000 g/mol to about 100,000 g/mol, about 1,000 g/mol to about 90,000 g/mol, about 1,000 g/mol to about 80,000 g/mol, about 1,000 g/mol to about 70,000 g/mol, about 1,000 g/mol to about 60,000 g/mol, about 1,000 g/mol to about 50,000 g/mol, about 1,000 g/mol to about 40,000 g/mol, about 1,000 g/mol to about 30,000 g/mol, about 1,000 g/mol to about 20,000 g/mol, about 1,000 g/mol to about 10,000 g/mol, about 1,000 g/mol to about 9,000 g/mol, about 1,000 g/mol to about 8,000 g/mol, about 1,000 g/mol to about 7,000 g/mol, about 1,000 g/mol to about 6,000 g/mol, about 1,000 g/mol to about 5,000 g/mol, about 1,500 g/mol to about 10,000 g/mol, about 1,500 g/mol to about 9,000 g/mol, about 1,500 g/mol to about 8,000 g/mol, about 1,500 g/mol to about 7,000 g/mol, about 2,000 g/mol to about 10,000 g/mol, about 2,000 g/mol to about 9,000 g/mol, about 2,000 g/mol to about 8,000 g/mol, about 2,000 g/mol to about 7,000 g/mol, about 2,000 g/mol to about 6,500 g/mol, about 2,000 g/mol to about 6,000 g/mol, about 2,000 g/mol to about 5,500 g/mol, about 2,000 g/mol to about 5,000 g/mol, about 2,000 g/mol to about 4,500 g/mol, about 2,500 g/mol to about 4,500 g/mol, or about 3,000 g/mol to about 4,500 g/mol.

Because the siloxane copolymer represented by Chemical Formula 1 may have a weight average molecular weight in the above range, the layer manufactured therefrom may have a low refractive index and may be less likely to generate cracks.

The siloxane copolymer represented by Chemical Formula 1 may be prepared by hydrolyzing and condensing a silane compound represented by Chemical Formula 2 below and a carbosilane compound represented by Chemical Formula 3.

(R¹)ₙ—Si—(OR²)₄₋ₙ [Chemical Formula 2]

In Chemical Formula 2, R¹ may be or include, e.g., hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C6 to C30 aryl group, a substituted or unsubstituted C3 to C30 cycloalkyl group, a substituted or unsubstituted C2 to C30 heterocycloalkyl group, a substituted or unsubstituted C1 to C30 alkoxy group, a carboxyl group, R(C═O)—, R(C═O)O— (wherein, R is hydrogen, a C1 to C30 alkyl group, a C3 to C30 cycloalkyl group, a C6 to C30 aryl group, or a combination thereof), an epoxy group-containing monovalent organic group, a (meth)acryloyloxy group, a (meth)acrylate group, an aminoalkyl group, or a combination thereof.

R² may be or include, e.g., hydrogen, or one of a C1 to C30 alkyl group, a C3 to C30 cycloalkyl group, a C2 to C30 alkenyl group, or a C6 to C30 aryl group.

0≤n<4.

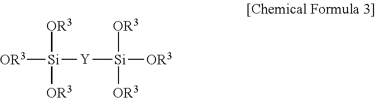

In Chemical Formula 3, R³s may each independently be or include, e.g., hydrogen, a C1 to C30 alkyl group, a C3 to C30 cycloalkyl group, a C2 to C30 alkenyl group, or a C6 to C30 aryl group.

Y may be or include, e.g., a substituted or unsubstituted C1 to C30 alkylene group, a substituted or unsubstituted C2 to C30 alkenylene group, a substituted or unsubstituted C3 to C30 cycloalkylene group, a substituted or unsubstituted C6 to C30 arylene group, or a combination thereof.

In Chemical Formula 2, n may be 0≤n≤3.

The hydrolysis condensation polymerization reaction of the silane compound represented by Chemical Formula 2 and the carbosilane compound represented by Chemical Formula 3 may be performed under an acid catalyst or a base catalyst in a solvent including water. In an implementation, the hydrolysis condensation polymerization reaction may be performed under an acid catalyst.

In Chemical Formula 1 to Chemical Formula 3, “substituted” may refer to substation of each functional group with an alkyl group, an alkenyl group, an alkynyl group, an aryl group, a hydroxy group, a carboxyl group, an epoxy group, a (meth)acryloyl group, a (meth)acrylate group, a cyano group, a nitro group, a halogen, or a combination thereof.

In Chemical Formula 2, R¹ may be, e.g., a C1 to C10 alkyl group, a C3 to C20 cycloalkyl group, an epoxy group-containing monovalent organic group, a C6 to C20 aryl group, a (meth)acryloyl group, a (meth)acrylate group, an alkyl group substituted with a (meth)acryloyl group, an alkyl group substituted with a (meth)acrylate group, an alkyl group substituted with an amino group, or a combination thereof.

In an implementation, the silane compound represented by Chemical Formula 2 may include, e.g., tetramethylorthosilicate (TMOS), tetraethylorthosilicate (TEOS) tetraisopropoxysilane, methyltrimethoxysilane, dimethyldimethoxysilane, phenyltrimethoxysilane, diphenyldimethoxysilane, methyltriethoxysilane, dimethyldiethoxysilane, phenyltriethoxysilane, diphenyldiethoxysilane, isobutyltrimethoxysilane, vinyltrimethoxysilane, vinyltriethoxysilane, vinyltris(β-methoxyethoxy)silane, 3,3,3-trifluoropropyltrimethoxysilane, methyl-3,3,3-trifluoropropyldimethoxysilane, β-(3,4-epoxycyclohexyl)ethyltrimethoxysilane, γ-glycidoxytripropyltrimethoxysilane, γ-glycidoxypropylmethyldiethoxysilane, γ-glycidoxypropyltriethoxysilane, γ-methacryloyloxypropylmethyldimethoxysilane, γ-methacryloyloxypropyltrimethoxysilane, γ-methacryloyloxypropylmethyldiethoxysilane, γ-methacryloyloxypropyltriethoxysilane, N-β(aminoethyl)-γ-aminopropylmethyldimethoxysilane, N-β(aminoethyl)-γ-aminopropyltrimethoxysilane, N-β(aminoethyl)-γ-aminopropyltriethoxysilane, γ-aminopropyltrimethoxysilane, γ-aminopropyltriethoxysilane, N-phenyl-γ-aminopropyltrimethoxysilane, γ-mercaptopropyltrimethoxysilane, acryloyloxypropyltrimethoxysilane, trimethyl silanol, methyltrichlorosilane, methyldichlorosilane, dimethyldichlorosilane, trimethylchlorosilane, phenyltrichlorosilane, diphenyldichlorosilane, vinyltrichlorosilane, trimethylbromosilane, diethylsilane, or the like.

In an implementation, the carbosilane compound represented by Chemical Formula 3 may include, e.g., 1,2-bis-trimethoxysilylethane, 1,2-bis-triethoxysilylethane, 1,4-bis-trimethoxysilylcyclohexane, or the like.

The siloxane copolymer represented by Chemical Formula 1 may be included in an amount of about 1 wt % to about 50 wt %, e.g., about 1 wt % to about 45 wt %, about 1 wt % to about 40 wt %, about 1 wt % to about 35 wt %, about 5 wt % to about 50 wt %, about 5 wt % to about 45 wt %, about 5 wt % to about 40 wt %, about 5 wt % to about 35 wt %, about 10 wt % to about 50 wt %, about 10 wt % to about 45 wt %, about 10 wt % to about 40 wt %, about 10 wt % to about 35 wt %, about 15 wt % to about 50 wt %, about 15 wt % to about 45 wt %, about 15 wt % to about 40 wt %, about 15 wt % to about 35 wt %, about 20 wt % to about 50 wt %, about 20 wt % to about 45 wt %, about 20 wt % to about 40 wt %, about 20 wt % to about 35 wt %, based on a total weight of the curable resin composition.

Because the siloxane copolymer represented by Chemical Formula 1 may be included in the above ranges in the curable resin composition according to some embodiments, the layer manufactured therefrom may exhibit a low refractive index and low haze, and may have mechanical properties such as high indentation hardness and excellent crack resistance.

### (b) Hollow Particles

The curable resin composition according to some embodiments may include hollow particles to further reduce the refractive index of the layer. The hollow particles may be hollow particles of metal oxide, e.g., silicon oxide, aluminum oxide, titanium oxide, zirconium oxide, or zinc oxide, and may be hollow silica particles.

The siloxane copolymer included in the curable resin composition according to some embodiments may have a low refractive index characteristic by itself, and if hollow particles are mixed with such siloxane copolymer, the refractive index of the layer manufactured from the resin composition may be further reduced due to the pores within the hollow particles.

In an implementation, the hollow silica particles may include, e.g., a silane compound on their surface. If the surface of the hollow silica particles is treated with a silane compound, e.g., a silane compound such as that represented by Chemical Formula 2 used to prepare the siloxane copolymer included in the curable resin composition, the silane compound may be bonded to the surface of the hollow silica particles. The hollow silica particles including a silane compound on the surface may further improve compatibility with the siloxane copolymer in the curable resin composition. In an implementation, the silane compound capable of being bonded to the surface of the hollow silica particle may be, e.g., methyl trimethoxysilane or methacryloyloxypropyl trimethoxysilane.

A method of binding a silane compound to the surface of a hollow silica particle may be any suitable method. In an implementation, a silane compound may be dissolved or dispersed at an appropriate concentration in a suitable solvent, such as water, ethanol, or other suitable polar organic solvent, and then hollow silica particles may be added to this solution and stirred to react them. In addition to these methods, particles in which a silane compound may be bonded to the surface of hollow silica particles may be manufactured by various suitable methods.

The average diameter (D₅₀) of the hollow silica particles may be about 10 nm to about 300 nm, e.g., about 10 nm to about 250 nm. Maintaining the average diameter size of the hollow silica particles within the above ranges may help ensure that they may be well dispersed in the curable resin composition including the siloxane copolymer according to some embodiments, the refractive index of the cured layer may be efficiently reduced, and the effect of increasing the indentation hardness or improving the crack resistance of the layer may be realized.

A porosity of the hollow silica particles may be, e.g., about 40% to about 90% or about 40% to about 80%.

The hollow silica particles may be included in amount of about 1 wt % to about 35 wt %, e.g., about 1 wt % to about 30 wt %, about 5 wt % to about 35 wt %, about 5 wt % to about 30 wt %, about 10 wt % to about 35 wt %, about 10 wt % to about 30 wt %, about 15 wt % to about 35 wt %, about 15 wt % to about 30 wt %, about 20 wt % to about 35 wt %, or about 20 wt % to about 30 wt %, based on the total weight of the curable resin composition according to some embodiments.

### (c) Solvent

The solvent included in the curable resin composition according to some embodiments may be used alone or in a mixture of two or more solvents. The solvent may be an organic solvent, e.g., alcohols (e.g., 4-methyl-2-pentanol, 4-methyl-2-propanol, 1-butanol, methanol, isopropyl alcohol, or 1-propanol), ethers (e.g., anisole, tetrahydrofuran, diethylene glycol methyl ethyl ether, or triethylene glycol monomethyl ether), esters (e.g., n-butyl acetate, propylene glycol monomethyl ether acetate, ethyl acetate, or ethyl lactate), ketones (e.g., γ-butyrolactone, methyl ethyl ketone, or 2-heptanone), or mixtures thereof.

The solvent may be included in an amount of about 30 wt % to about 95 wt %, e.g., about 30 wt % to about 90 wt %, about 35 wt % to about 90 wt %, or about 40 wt % to about 90 wt %, based on a total weight of the curable resin composition, and may be appropriately adjusted depending on the total solid content.

### (d) Other Additives

The curable resin composition according to some embodiments may further include various additives known in the art. These additives may further include, e.g., a surfactant, e.g., a fluorine or a silicone surfactant to improve coating properties and prevent defects when coating the composition. These additives may be included in an amount of about 0.1 to about 3 wt %, based on a total curable resin composition.

Some embodiments may provide a thin layer manufactured by curing the curable resin composition.

Some embodiments may provide a color conversion panel including the thin layer.

The color conversion panel may include, e.g., a substrate; a low refractive index layer on one surface of the substrate; a color conversion layer including a color conversion member disposed on the low refractive index layer or between the low refractive index layer and the substrate; and a planarization layer covering the low refractive index layer and the color conversion layer, wherein the low refractive index layer may be manufactured from the curable resin composition according to some embodiments.

Herein, because the curable resin composition may be the same as described above, detailed description thereof will be omitted.

In an implementation, the low refractive index layer of the color conversion panel may be manufactured by coating the substrate or the color conversion layer with a curable resin composition according to some embodiments and curing it. In an implementation, if the curable resin composition is coated on a substrate or a color conversion layer formed on the substrate, the curable resin composition may be dried and cured at a temperature of greater than or equal to about 150° C. and less than or equal to about 250° C., e.g., greater than or equal to about 170° C. and less than or equal to about 250° C., greater than or equal to about 180° C. and less than or equal to about 250° C., greater than or equal to about 180° C. and less than or equal to about 240° C., greater than or equal to about 190° C. and less than or equal to about 240° C., greater than or equal to about 200° C. and less than or equal to about 240° C., greater than or equal to about 210° C. and less than or equal to about 240° C., or greater than or equal to about 220° C. and less than or equal to about 240° C. for about 10 minutes to about 1 hour.

The method of coating the composition on the substrate or the color conversion layer may be any suitable method, e.g., spin coating, slit and spin coating, slit coating, roll coating, or die coating. In an implementation, the composition may be spin-coated onto a substrate or color conversion layer.

The low refractive index layer manufactured as above may have a thickness of about 100 nm to about 10 μm. In an implementation, the thin layer may have a thickness of about 1 μm to about 10 μm, e.g., about 1 μm to about 8 μm, about 1 μm to about 7 μm, or about 1 μm to about 6.5 μm.

Hereinafter, a color conversion panel according to some embodiments will be described in detail with reference to the drawings.

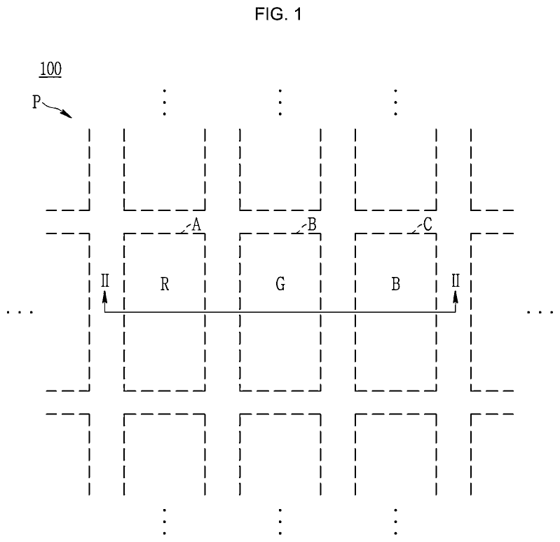

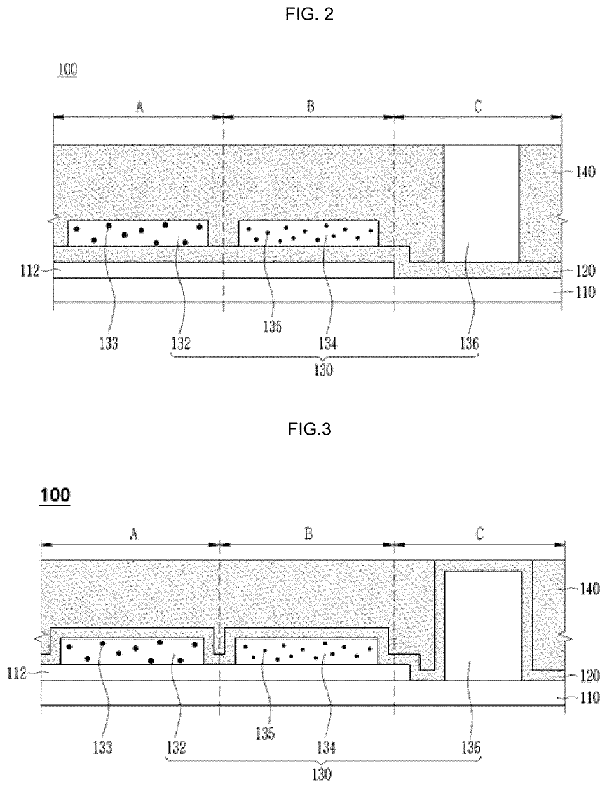

FIG. 1 is a plan view schematically showing a color conversion panel 100 according to some embodiments, and FIGS. 2 and 3 are schematic cross-sectional views taken along line II-II of FIG. 1, respectively.

Referring to FIGS. 2 and 3, a color conversion panel 100 according to some embodiments may include a substrate 110, a low refractive index layer 120, a color conversion layer 130, and a planarization layer 140, wherein the color conversion layer 130 may include color conversion layers that emit light in at least two different wavelengths such as a first color conversion layer 132 that emits light in a first wavelength in a first region A and a second color conversion layer 134 that emits light in a second wavelength in a second region B. In an implementation, the first color conversion layer 132 may emit red (R) light, and the second color conversion layer 134 may emit green (G) light. In an implementation, the color conversion panel 100 may further include a third region C that emits blue (B) light or white light.

The substrate 110 may be made of a transparent and electrically insulative material and a protective layer 112 may be further included at positions corresponding to the first color conversion layer 132 and the second color conversion layer 134. The protective layer 112 may be formed on one surface of the substrate 110 and may help ensure patterning of the color conversion layer may be performed smoothly and may help protect a color conversion member inside the color conversion layer if the color conversion layer 130 is formed on the substrate 110.

The low refractive index layer 120 may cover a portion of the substrate 110 and the protective layer 112 on one surface of the substrate 110, e.g., on one surface of the substrate 110 on which the protective layer 112 may be formed or, as shown in FIG. 3, the color conversion layer 130 may be first stacked on the protective layer 112, and then the low refractive index layer 120 may be stacked on the color conversion layer 130 to cover all of the color conversion layer 130, a portion of the substrate 110, and a portion of the protective layer 112. That is, between FIGS. 2 and 3, the only difference is that the low refractive index layer 120 may be located under the color conversion layer 130 (in the case of FIG. 2), or the low refractive index layer 120 may be located on the color conversion layer 130. This may be the only difference between FIG. 2 and FIG. 3, and all other components may be the same.

The low refractive index layer 120 according to some embodiments may have a relatively low refractive index for wavelengths of about 500 nm to about 550 nm of less than or equal to about 1.35, e.g., less than or equal to about 1.32, less than or equal to about 1.31, less than or equal to about 1.30, less than or equal to about 1.29, less than or equal to about 1.28, less than or equal to about 1.27, less than or equal to about 1.26, less than or equal to about 1.25, less than or equal to about 1.24, or less than or equal to about 1.23. Forming the low refractive index layer 120 on an upper surface or a lower surface of the color conversion layer 130, or on both the upper and lower surfaces of the color conversion layer 130, may help ensure that light emitted from the color conversion layer 130 may be prevented from being reflected toward the substrate 110. In an implementation, as light passes through the low refractive index layer 120, it may be reflected or refracted due to a difference in refractive index and may move back toward the color conversion layer 130, resulting in the effect of reusing the lost light. In an implementation, the luminous efficiency of the color conversion panel 100 according to some embodiments in which the low refractive index layer 120 may be formed on an upper surface or a lower surface, or on both the upper and lower surfaces of the color conversion layer 130 may be further improved. The refractive index mentioned in this specification refers to the absolute refractive index representing the ratio of the speed of light in a vacuum and in a medium.

In addition, the low refractive index layer may have an average light transmittance for wavelengths of about 400 nm to about 800 nm of greater than or equal to about 90%, e.g., greater than or equal to about 91%, greater than or equal to about 92%, greater than or equal to about 93%, greater than or equal to about 94%, greater than or equal to about 95%, greater than or equal to about 96%, greater than or equal to about 97%, greater than or equal to about 98%, or greater than or equal to about 99%. Maintaining the average value of light transmittance for a wavelength of about 400 nm to about 800 nm of the low refractive index layer within the above ranges may help ensure that the optical characteristics of the low refractive index layer may be further improved.

In an implementation, the low refractive index layer may have an average reflectance (SCE value) of less than or equal to about 10%, e.g., less than or equal to about 7%, less than or equal to about 5%, or less than or equal to about 3% in the entire wavelength range of about 400 nm to about 800 nm, which corresponds to the visible light range. In an implementation, the color conversion panel 100 according to some embodiments may have high light transmittance even at a low wavelength range, and may maintain a low reflectance through an entire region of a visible ray wavelength to further improve optical characteristics.

The first color conversion layer 132 and the second color conversion layer 134 may respectively include a first color conversion member 133 emitting light in a first wavelength and a second color conversion member 135 emitting light in a second wavelength, and each of the first color conversion member 133 and the second color conversion member 135 may include quantum dots that convert a wavelength of incident light into light of other wavelengths. These color conversion members may be formed by applying a composition for forming a color conversion layer including quantum dots onto the substrate or the low refractive index layer 120 formed on the substrate. The composition for forming the color conversion layer may include quantum dots, a binder resin, a photopolymerizable monomer, a photopolymerization initiator, solvent, or other additives.

In an implementation, the color conversion layer 130 may be formed by coating a composition for forming a color conversion layer including color conversion members 133 and 135 including quantum dots, on the substrate 110 or the low refractive index layer 120 formed on the substrate 110, and then performing a patterning process. The patterning process may be performed by, e.g., coating the composition for forming the color conversion layer on the substrate 110 or the low refractive index layer 120 by a method such as a spin or slit coat method, a roll coat method, a screen printing method, or an applicator method and drying to form a coating layer, an exposing to form a pattern of a shape corresponding to the first color conversion layer 132 and the second color conversion layer 134 using a mask, developing to remove unnecessary portions, and a post-treatment step of curing by heating again or irradiating active rays, in order to obtain a pattern excellent in terms of heat resistance, light resistance, adhesion, crack resistance, chemical resistance, high strength, storage or stability.

The first and second color conversion layers 132 and 134 may further include a light scatterer in addition to the color conversion members 133 and 135 including the quantum dots. The light scatterer may be dispersed in the color conversion layer 130 along with the quantum dots. The light scatterer may induce incident light to reach the quantum dots or a radiation direction so that radiated light emitted from the quantum dots may be emitted outside from the color conversion layer 130. Thereby, decrease in luminous efficiency of the color conversion layer 130 may be minimized. The transmission member 136 may also include a light scatterer.

The planarization layer 140 may be formed on the low refractive index layer 120 and the color conversion layer 130. The planarization layer 140 may cover the low refractive index layer 120 and the color conversion layer 130 to protect them and planarizes the surface of the color conversion panel 100. The planarization layer 140 may be made of a transparent and electrically insulative material so that light may be transmitted. In an implementation, the planarization layer 140 may be made of the same or different polymer matrix as the low refractive index layer 120. In an implementation, the planarization layer 140 may be made of a low refractive index material including the carbosilane-siloxane copolymer like the low refractive index layer 120 and thereby luminous efficiency of the color conversion panel 100 may be further improved. In an implementation, if incident light of the low refractive index layer 120 enters the planarization layer 140, reflection or scattering may be minimized, and thereby optical loss at the interface may be minimized to provide the color conversion panel 100 having improved light efficiency.

In an implementation, the color conversion layer 130 may further include a transmission member 136 corresponding to the third region C. The transmission member 136 may emit light received from a light source as itself without separate color conversion. In an implementation, the transmission member 136 may be formed to be the same as the height of the color conversion layer 130. In an implementation, as shown in FIGS. 2 and 3, the transmission member 136 may exist as an empty space that is not filled with anything. For example, as can be seen in FIGS. 2 and 3, the transmission member 136 may not include any additional components, e.g., quantum dots. In an implementation, the transmission member 136 may include quantum dots to emit light converted to a specific wavelength, like the first color conversion layer 132 and the second color conversion layer 134, and may further include the light scatterer described above.

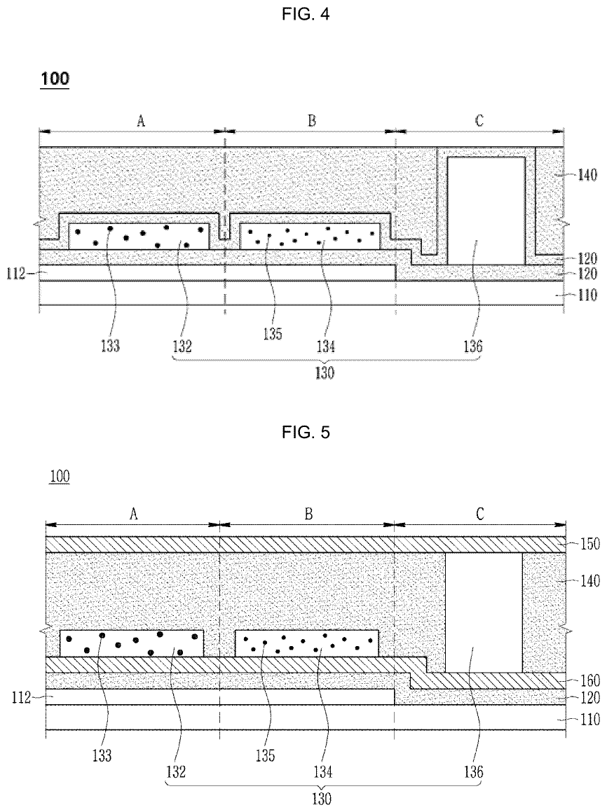

FIG. 4 is a cross-sectional view according to a modification embodiment of FIGS. 2 and 3. FIG. 4 is a cross-sectional view showing an example in which the low refractive index layer 120 may be formed on both the upper and lower surfaces of the color conversion layer 130. Except that the low refractive index layer 120 is formed on both the upper and lower surfaces of the color conversion layer 130, the remaining components are all the same as those described in FIGS. 2 and 3, and thus detailed descriptions therefor will be omitted. Including the low refractive index layer 120 on both the upper and lower surfaces of the color conversion layer 130 as shown in FIG. 4, may help ensure that the luminous efficiency of the color conversion panel 100 may be further improved.

FIG. 5 is a cross-sectional view according to a modification embodiment of FIG. 2. Referring to FIG. 5, the color conversion panel 100 according to one modification embodiment may further include a first capping layer 150 and a second capping layer 160. FIG. 5 shows a modification embodiment including both the first capping layer 150 and the second capping layer 160, but either one of them may be omitted.

The first capping layer 150 may be formed on the planarization layer 140 and may cover the planarization layer 140. In an implementation, the first capping layer may be formed after forming the planarization layer 140. The first capping layer 150 may be formed over the entire surface of the substrate 110.

The second capping layer 160 may be formed between the low refractive index layer 120 and the color conversion layer 130 and may be formed on the entire surface of the substrate 110, like the first capping layer 150. In an implementation, the second capping layer 160 may be formed between a forming process of the low refractive index layer 120 and a forming process of the color conversion layer 130.

The first capping layer 150 and the second capping layer 160 may also be made of a material having a low refractive index, e.g., SiNₓ, like the low refractive index layer 120. A first capping layer 150 that may form an interface with the planarization layer 140, and the second capping layer 160 that may be located between the low refractive index layer 120 and the planarization layer 140, or between the low refractive index layer 120 and the color conversion layer 130 and may form the interface with them, may also be made of a material with a low refractive index, and light incident on the first capping layer 150 and the second capping layer 160 that may be reflected or scattered may therefore be minimized. In an implementation, it may be possible to provide a color conversion panel 100 with improved light efficiency by minimizing optical loss at the interface.

In the case of the color conversion panel 100 including the first capping layer 150 and the second capping layer 160, the luminous efficiency may be increased by more than 150% compared to the color conversion panel 100 that does not include the low refractive index layer 120, the first capping layer 150, and the second capping layer 160 at all.

Above, the color conversion panel 100 according to some embodiments and a method of manufacturing the same have been described. According to this, it may be possible to provide a color conversion panel 100 including quantum dots, etc., in which luminous efficiency by the quantum dots may be improved.

Some embodiments provide a display device including the color conversion panel according to the aforementioned embodiment.

The display device may be a display device using quantum dots, OLED, mini LED, micro LED, nanorod LED, etc., or a flexible display device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthesis Example 1: Preparation of Siloxane Copolymer (A)

99.34 g (0.4 mol) of methacryloyloxypropyltrimethoxysilane (MPTMS), 104.16 g (0.5 mol) of tetraethyl orthosilicate (TEOS), 12.0 g (0.1 mol) of dimethyldimethoxysilane (DMDMS), and 192.40 g of propylene glycolmethyletheracetate (PGMEA) were added to a flask, and while stirring at room temperature, a hydrochloric acid aqueous solution prepared by dissolving 0.093 g (286 ppm) of hydrochloric acid in 33.10 g of water was added thereto over a period of 10 minutes. Subsequently, after placing the flask in an oil bath at 60° C. and stirring it for 180 minutes, 67.3 g of the reaction by-products such as methanol, ethanol, a hydrochloric acid aqueous solution, and water were discharged therefrom for 180 minutes by using a vacuum pump and a Dean-Stark, obtaining a siloxane copolymer (A) solution as a product. In the solution, a siloxane copolymer (A) had a solid concentration of 22 wt %. The obtained siloxane copolymer (A) had a polystyrene converted weight average molecular weight of 4,000 g/mol. The weight average molecular weight was measured using gel permeation chromatography (GPC: HLC-8220GPC, Tosoh Corp.).

### Synthesis Example 2: Preparation of Siloxane Copolymer (B)

A siloxane copolymer (B) solution was obtained in the same manner as in Synthesis Example 1 except that 99.34 g (0.4 mol) of MPTMS, 114.576 g (0.55 mol) of TEOS, and 6.0 g (0.05 mol) of DMDMS were used. In the solution, a siloxane copolymer (B) had a solid concentration of 20 wt %. The obtained siloxane copolymer (B) had a polystyrene converted weight average molecular weight of 4,000 g/mol. The weight average molecular weight was measured using gel permeation chromatography (GPC: HLC-8220GPC, Tosoh Corp.).

### Synthesis Example 3: Preparation of Siloxane Copolymer (C)

A siloxane copolymer (C) solution was obtained in the same manner as in Synthesis Example 1 except that 99.34 g (0.4 mol) of MPTMS, 122.9 g (0.59 mol) of TEOS, and 1.2 g (0.01 mol) of DMDMS were used. In the solution, a siloxane copolymer (C) had a solid concentration of 20 wt %. The obtained siloxane copolymer (C) had a polystyrene converted weight average molecular weight of 4,000 g/mol. The weight average molecular weight was measured using gel permeation chromatography (GPC: HLC-8220GPC, Tosoh Corp.).

### Comparative Synthesis Example 1: Preparation of Siloxane Copolymer (D)

A siloxane copolymer (D) solution was obtained in the same manner as in Synthesis Example 1 except that 99.34 g (0.4 mol) of MPTMS, 83.328 g of TEOS, and 24.0 g (0.2 mol) of DMDMS were used. In the solution, a siloxane copolymer (D) had a solid concentration of 20 wt %. The obtained siloxane copolymer (D) had a polystyrene converted weight average molecular weight of 4,000 g/mol. The weight average molecular weight was measured using gel permeation chromatography (GPC: HLC-8220GPC, Tosoh Corp.).

### Comparative Synthesis Example 2: Preparation of Siloxane Copolymer (E)

A siloxane copolymer (E) was prepared in the same manner as in Comparative Synthesis Example 1, but a tetramethylammonium hydroxide (TMAH) aqueous solution at a concentration of 100 ppm instead of the hydrochloric acid aqueous solution was added to a solution including a mixture of the silane monomers to perform a polymerization reaction.

The siloxane copolymer (E) obtained from the reaction had a polystyrene converted weight average molecular weight of 4,000 g/mol. The weight average molecular weight was measured using gel permeation chromatography (GPC: HLC-8220GPC, Tosoh Corp.).

### Synthesis Example 4: Preparation of Surface-Treated Hollow Silica Particles

A dispersion of hollow silica particles having an average particle diameter (D₅₀) of 100 nm and surface-treated with methacryloyloxypropyltrimethoxysilane (a silica solid content of 20%, L0516, Nano Advanced Materials Co., Ltd.) was used.

### Examples 1 to 3 and Comparative Examples 1 and 2: Preparation of Curable Resin Compositions

Each of the siloxane copolymer solutions according to Synthesis Examples 1 to 3, the hollow silica particle dispersion according to Synthesis Example 4 (a silica solid content: 20%, L0516, Nano Advanced Materials Co., Ltd.), PGMEA as a solvent, and F-563 (DIC Co., Ltd.), which is a surfactant including fluorine, were mixed in ratios shown in Table 1 based on a total weight of each composition, preparing curable resin compositions according to Examples 1 to 3.

In addition, the solutions according to Comparative Synthesis Examples 1 and 2, as a siloxane copolymer solution, were respectively used to prepare each curable resin composition according to Comparative Examples 1 and 2 in the same manner as the method of preparing the curable resin compositions according to Examples 1 to 3.

### Preparation and Evaluation of Cured Layers

Each of the compositions according to Examples 1 to 3 and Comparative Examples 1 and 2 was formed into cured layers, and each of the cured layers was measured with respect to a refractive index, haze, a crack margin, and indentation hardness, and the results are shown in Table 1. In addition, whether or not a panel including each of the cured layers was cracked was checked, and the results are shown in Table 1. Each of the cured layers was measured with respect to a thickness by using Alpha-step (Surface profiler, KLA-Tencor Corp.), and each evaluation was performed according to the following methods.

### (1) Refractive Index

Each of the compositions according to the Examples and the Comparative Examples was coated on a silicon wafer with a diameter of 4 inches by using a spin coater (Opticoat MS-A100, Mikasa Co., Ltd.), and then, pre-baked on a hot plate at 100° C. for 2 minutes to form films. Subsequently, the films were cured at 230° C. for 20 minutes and dried, obtaining each 2.0 μm-thick cured layer. Each obtained cured layer was measured with respect to a refractive index by using an Ellipsometer (Base-160, J. A. Woollam) at 550 nm, and the results are shown in Table 1.

### (2) Haze

Each cured layer with a thickness of 2.0 μm was obtained in the same manner as the method of manufacturing the cured layers for measuring the refractive index except that each of the compositions according to the Examples and the Comparative Examples was spin-coated on a glass substrate instead of the silicon wafer. Each obtained cured layer was measured with respect to a haze by using a hazemeter at a wavelength of 650 nm, and the results are shown in Table 1.

### (3) Crack Margin

A crack margin refers to a thickness of each cured layer at which cracks began to occur. If a cured layer formed of a curable resin composition including a siloxane copolymer becomes thicker than a predetermined thickness, the cured layer may be cracked. Accordingly, as the thickness of the cured layer at which cracks begin to occur is thicker, the crack margin may be larger, which means that the cracks may occur less on the corresponding cured layer.

A method of measuring the crack margin, like the method of measuring the haze, was performed by spin-coating each of the curable resin compositions according to the Examples and the Comparative Examples on a glass substrate and curing it to obtain cured layers. Herein, if the cured layers were not cracked, a portion of the cured layers was cut off with a razor blade and then, measured with respect to a thickness with KLA P-6 made by Tencor Corp. Subsequently, in order to make the cured layers thicker, each of the resin compositions was more thickly coated and then, cured to check whether or not the corresponding cured layers were cracked. In this way, a maximum thickness of the cured layers before the cracks occurred was measured as the crack margin, and the results are shown in Table 1.

### (4) Indentation Hardness

Each of the curable resin compositions according to the Examples and the Comparative Examples was coated and cured on a silicon wafer to obtain each cured layer with a thickness of about 2.0 μm in the same manner as the method of manufacturing the cured layers for measuring the refractive index. The cured layers were pressed at 100 μN by using a nanoindentor to measure indentation hardness, and the results are shown in Table 1.

TABLE 1

| | Composition* (wt %) | | | | | | | | |
|---|---|---|---|---|---|---|---|---|---|
| | Siloxane | | | | Optical | | Mechanical properties | | |
| | copolymer | Hollow | | | characteristics | | Crack | Indentation | Presence or |
| | solution | Particle | Solvent | | Refractive | | margin | hardness | absence of |
| | (amount) | dispersion | (PGMEA) | F-563 | index | Haze | (μm) | (GPa) | panel cracks |
| Example1 | Synthesis | 25 | 42 | 1 | 1.229 | 0.9 | 6.2 | 0.125 | Absence |
| | Example 1 | | | | | | | | |
| | (32) | | | | | | | | |
| Example2 | Synthesis | 27 | 42 | 1 | 1.226 | 1.1 | 6.0 | 0.135 | Absence |
| | Example 2 | | | | | | | | |
| | (30) | | | | | | | | |
| Example3 | Synthesis | 29 | 41 | 1 | 1.218 | 1.2 | 5.8 | 0.145 | Absence |
| | Example 3 | | | | | | | | |
| | (29) | | | | | | | | |
| Comparative | Comparative | 25 | 42 | 1 | 1.231 | 0.8 | 7.0 | 0.115 | Cracks |
| Example1 | Synthesis | | | | | | | | occurred |
| | Example 1 | | | | | | | | |
| | (32) | | | | | | | | |
| Comparative | Comparative | 29 | 38 | 1 | 1.221 | 0.6 | 5.8 | 0.130 | Cracks |
| Example2 | Synthesis | | | | | | | | occurred |
| | Example 2 | | | | | | | | |
| | (32) | | | | | | | | |

*based on a total weight of the curable resin composition.

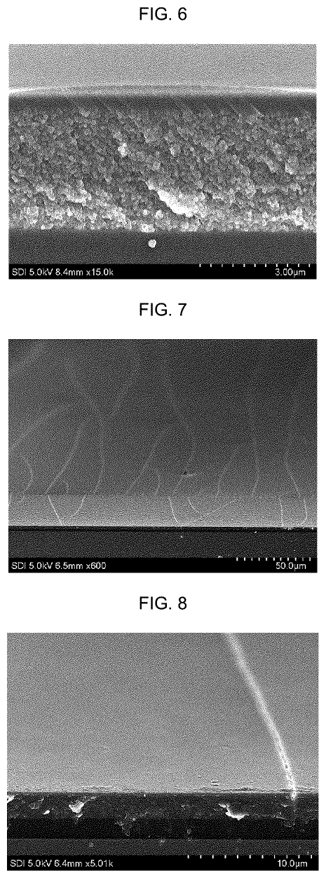

As shown in Table 1, the cured layers formed of the curable resin compositions according to Examples 1 to 3 including the curable resin composition according to some embodiments exhibited a low refractive index of 1.229 or less and thus had low refractive index characteristics and also, exhibited a sufficiently low haze of 1.2 and thus exhibited transparent film characteristics. In addition, the cured layers according to Examples 1 to 3 exhibited a sufficient crack margin of at least 5.8 μm or more and high indentation hardness of 0.125 GPa or more and thus had sufficient mechanical properties. When such cured layers were applied as low refractive index layers of color conversion panels including QD color filters, the panel were not cracked even at a high temperature process. FIG. 6 is a transmission electron microscope (TEM) image showing a cross-section of the cured layer according to Example 3, wherein the cured layer was not cracked even at a thickness of about 4 μm or more.

On the other hand, the cured layer formed of the curable resin composition of Comparative Example 1 exhibited a refractive index of 1.231 or less and thus low refractive index characteristics and also, a low haze of 0.8 and thus excellent optical characteristics. In addition, the cured layer exhibited a very high crack margin of 7.0 μm but relatively low indentation hardness of 0.115 GPa, which is less than 0.12 GPa. Accordingly, when the cured layer of Comparative Example 1 was applied as a low refractive index layer of a color conversion panels including QD color filters, the panel was cracked in the high temperature process. In other words, the cured layer according to Comparative Example 1 itself had a high margin but when processed at the high temperature process to be applied to the panel, the panel was cracked. FIG. 7 is a scanning electron microscope image showing that the panel to which the cured layer of Comparative Example 1 was applied was cracked.

On the other hand, the curable resin compositions according to Comparative Examples 1 and 2 included a siloxane copolymer with the same components, but because the copolymer of Comparative Examples 2 unlike Comparative Example 1 was prepared by adding a basic catalyst (TMAH) rather than acid, the cured layer formed thereof exhibited different characteristics from the cured layer of Comparative Example 1. The cured layer of Comparative Example 2 exhibited a low refractive index of 1.22 and thus satisfied low refractive index characteristics and in addition, a very low haze of 0.6 and thus excellent optical characteristics. In addition, the cured layer itself exhibited a sufficient crack margin of 5.8 μm and also, sufficiently high indentation hardness of 0.130 GPa. However, when the cured layer of Comparative Example 2 was processed through the high temperature process in order to be applied as a low refractive index layer to color conversion panels including QD color filters, the panel was cracked, which was similar to the cured layer of Comparative Example 1. FIG. 8 is a scanning electron microscope (SEM) image showing that the panel to which the cured layer of Comparative Example 2 was applied was cracked.

As a result, the cured layers according to Examples 1 to 3 including the curable resin compositions according to some embodiments achieved a low refractive index and a low haze and thus satisfied excellent optical characteristics, provided a sufficient crack margin, and exhibited high indentation hardness and thus excellent mechanical properties. In addition, even if these cured layers were applied onto a substrate including patterns at the bottom like QD color filters and thus having steps and subjected to the high temperature process, cracks did not occur during manufacturing the panel. Accordingly, the curable resin composition according to some embodiments had excellent optical characteristics and mechanical properties but no crack occurrence even at the high temperature process and thus turned out to be advantageously applied as low refractive index layer materials of various display devices.

One or more embodiments may provide a curable resin composition that may be excellent in both optical characteristics, e.g., low refractive index and high transparency, and mechanical properties, e.g., high indentation hardness and crack resistance.

Some embodiments may provide a thin layer manufactured by curing the composition.

Some embodiments may provide a color conversion panel including the thin layer.

Some embodiments may provide a display device including the color conversion panel.

The curable resin composition according to some embodiments may be cured at a low temperature, and the thin layer manufactured therefrom may have excellent optical characteristics such as low refractive index and low haze, and excellent mechanical properties such as high indentation hardness and crack resistance. Accordingly, a thin layer manufactured from the composition according to some embodiments can be advantageously used in various display devices.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A curable resin composition, comprising:
a silicon-containing polymer represented by Chemical Formula 1;
hollow particles; and
a solvent:
(R⁴R⁵R⁶SiO_{1/2})_{M}(R⁷R⁸SiO_{2/2})_{D}(R⁹SiO_{3/2})_{T1}(SiO_{3/2}—Y—SiO_{3/2})_{T2}(SiO_{4/2})_{Q} [Chemical Formula 1]
wherein, in Chemical Formula 1,
R⁴ to R⁹ are each independently hydrogen, or a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C6 to C30 aryl group, a substituted or unsubstituted C3 to C30 cycloalkyl group, a substituted or unsubstituted C2 to C30 heterocycloalkyl group, a substituted or unsubstituted C1 to C30 alkoxy group, a carboxyl group, R(C═O)—, R(C═O)O—, wherein, R is hydrogen, a C1 to C30 alkyl group, a C3 to C30 cycloalkyl group, a C6 to C30 aryl group, or a combination thereof, an epoxy group-containing monovalent organic group, a (meth)acryloyloxy group, a (meth)acrylate group, an aminoalkyl group, or a combination thereof,
Y is a substituted or unsubstituted C1 to C30 alkylene group, a substituted or unsubstituted C2 to C30 alkenylene group, a substituted or unsubstituted C3 to C30 cycloalkylene group, a substituted or unsubstituted C6 to C30 arylene group, or a combination thereof,
$$0 \leq M \leq 02 , 0 < D < 0.2 , 0.1 < T 1 \leq 0.5 , 0 \leq T 2 \leq 0.2 , 0 < Q \leq 0.65 , and$$
$$M + D + T 1 + T 2 + Q = 1 .$$

2. The curable resin composition as claimed in claim 1, wherein in Chemical Formula 1, 0≤M≤0.1, 0<D≤0.15, 0.2≤T1≤0.5, and 0.3≤Q≤0.65.

3. The curable resin composition as claimed in claim 1, wherein in Chemical Formula 1, 0≤M≤0.1, 0.01≤D≤0.1, 0.3≤T1≤0.45, and 0.5≤Q≤0.6.

4. The curable resin composition as claimed in claim 1, wherein the silicon-containing polymer has a polystyrene converted weight average molecular weight of about 1,000 g/mol to about 100,000 g/mol.

5. The curable resin composition as claimed in claim 1, wherein the silicon-containing polymer is included in an amount of about 1 wt % to about 50 wt %, based on a total weight of the curable resin composition.

6. The curable resin composition as claimed in claim 1, wherein the curable resin composition has a pH of about 4 to about 10.

7. The curable resin composition as claimed in claim 1, wherein the hollow particles have an average diameter (D₅₀) of about 10 nm to about 300 nm.

8. The curable resin composition as claimed in claim 1, wherein the hollow particles have an average porosity of about 40% to about 90%.

9. The curable resin composition as claimed in claim 1, wherein:
the hollow particles are hollow silica, and
the hollow silica includes a silane compound on its surface.

10. The curable resin composition as claimed in claim 1, wherein the hollow particles are included in an amount of about 1 wt % to about 35 wt %, based on a total weight of the curable resin composition.

11. The curable resin composition as claimed in claim 1, further comprising a fluorine surfactant or a siloxane surfactant.

12. A thin layer manufactured from the curable resin composition as claimed in claim 1.

13. A color conversion panel comprising the thin layer as claimed in claim 12.

14. A display device comprising the color conversion panel as claimed in claim 13.
